(19) United States
(12) Patent Application Publication
(10) Pub. No.: US 2025/0260924 A1
(43) Pub. Date: Aug. 14, 2025

(54) STEPPED CONTROL SYSTEM WITH DEDICATED INTEGRATED CIRCUIT

(71) Applicant: STETSOM INDUSTRIA ELETRÔNICA LTDA., Sao Paulo (BR)

(72) Inventors: Anderson Ferreira, Sao Paulo (BR); Marcio Akira Tamura Lopes, Sao Paulo (BR); Keops Roger Michelotto Koto, Sao Paulo (BR); Sergio Aparecido Almeida de Freitas, Sao Paulo (BR)

(21) Appl. No.: 19/048,669

(22) Filed: Feb. 7, 2025

(30) Foreign Application Priority Data
Feb. 8, 2024 (BR) 1020240026470

(51) Int. Cl. H04R 3/00; H03F 3/187; H04S 3/00

(52) U.S. Cl. CPC H04R 3/00; H04S 3/008; H03F 3/187; H03F 2200/03; H04R 2420/07; H04S 2400/01

(57) ABSTRACT

The present invention mainly relates to a stepped control system with dedicated integrated circuit to be applied in multimedia, processors, sound mixers or multimedia audio amplifiers comprising: a receiver circuit for analog and digital audio inputs; an audio processor circuit to perform the treatment of audio sources, the processor circuit comprising: a master MMIC acting as a digital and analog audio player and configured to receive at least one audio processing command from a user; and where the master MMIC receives the analog inputs from the analog audio input receiver circuit. Optionally, slave MMICs can be used in connection with the master MMIC for applications requiring additional channels (more than two). The slave MMICs receive analog and digital signals from the master MMIC, enabling digital audio traffic between the MMICs.

### TECHNICAL FIELD

The present invention relates to the field of multimedia, processors, sound mixers and audio amplifiers, more specifically to a stepped control system with a dedicated integrated circuit for use in these audio systems.

### BACKGROUND

In common prior art applications, audio equipment has RCA, XLR, P10, P3, P2, Speaker Input Wire and Card MP3 Player analog inputs, whose signals are mixed with the aid of analog circuits. If there is a need for processing, a DSP (Digital Signal Processor) is used to treat the audio and then pass it on to the amplification stage and/or various functionalities.

This printed circuit board known as Card MP3 Player has audio interfaces, a display for visualization, control buttons, power connections and audio outputs to be connected to an amplifier or the user's headphones. It is capable of playing MP3 audio from a Pendrive, SD Card, P2, P3, Streaming audio via Bluetooth with or without broadcasting functionality, receiving or transmitting signals. It has a Multi Media Integrated Circuit (MMIC) that handles audio processing, display management, FM reception and user interface via the buttons.

In this context, audio treatment means the purposeful, conscious and objective changes that are applied to a signal from an audio source in order to produce a desired output. For example, if the signal from an audio source is considered weak, one type of treatment would be to increase its gain before the amplification stage.

In addition, along with the use of the DSP, a microcontroller is required to perform the user interface function and send the parameters to the DSP. In some cases, Analog/Digital Converter (ADC) and Digital/Analog Converter (DAC) circuits are also required, which significantly increases the complexity of the circuit.

In addition, it is common knowledge that these audio processing items (i.e. Microcontroller, DSP and converters) have high values and are generally used in higher value-added applications or products with cutting-edge technology (High End), offering the user greater control and adjustments to their sound.

However, even for amplifier circuits in limited applications, it is common to see the use of the DSP (and therefore a microcontroller for the DSP) to perform only one or two specific functions, generating an overengineering of the circuit.

In view of this, it is clear that there is a need in the market for circuits aimed at Low-End and Mid-End applications, which do not make use of components that generate overengineering, such as DSP, microcontrollers and converters.

### Objectives

An aim of this patent application is to provide a stepped control system with a dedicated integrated circuit that can use the MMIC's internal audio processing resources to process audio from external sources, thus eliminating the microcontroller, the DSP and the converters, reducing the cost of the product, making it more accessible and properly sized for its applications.

It is also an objective of this patent application to provide a circuit that has easy scalability while maintaining a low production cost.

### SUMMARY

The present invention relates to a stepped control system with a dedicated integrated circuit for application, for example, in audio amplifiers. The stepped control system with dedicated integrated circuit comprises: a receiver circuit for analog and digital audio inputs; an audio processor circuit to handle the sources, the processor circuit comprising: a master MMIC acting as a digital audio player and configured to receive at least one audio processing command from a user; and where the master MMIC receives the analog inputs from the analog audio input receiver circuit, where the master MMIC receives the analog inputs from the analog audio input receiver circuit. The audio signals from the analog and digital inputs are routed to the audio outputs of the master MMIC after the audio has been processed by the master MMIC.

### BRIEF DESCRIPTION OF THE FIGURES

FIG. 1 shows a block diagram illustrating the topology of the base circuit of the stepped control system with dedicated integrated circuit of the present invention.

FIG. 2 illustrates a block diagram of an alternative embodiment of the stepped control system with a dedicated integrated circuit applied to a 4-channel amplifier with an RCA input.

FIG. 3 illustrates a block diagram of an alternative embodiment of the stepped control system with a dedicated integrated circuit applied to a 4-channel amplifier with RCA inputs and digitally processed or unprocessed Pre Out outputs.

FIG. 4 illustrates a block diagram of an alternative embodiment of the stepped control system with dedicated integrated circuit applied to a 4-channel amplifier with RCA and Speaker Input Wire inputs and auxiliary Pre Out outputs, processed or not, and digital audio inputs, SPDIF, USB, Bluetooth with or without broadcasting and FM receiver.

FIG. 5 illustrates a block diagram of an alternative embodiment of the stepped control system with dedicated integrated circuit applied to a 4-channel amplifier with RCA and Speaker Input Wire inputs, with processed or unprocessed auxiliary output.

FIG. 6 illustrates a block diagram of the stepped control system with dedicated integrated circuit according to an alternative embodiment of the present invention with two RCA inputs, two Speaker Input Wire inputs and 6 output channels.

FIG. 7 illustrates a block diagram of the stepped control system with dedicated integrated circuit according to an alternative embodiment of the present invention applied to a mixer with RCA, XLR and P10 inputs and RCA and P10 outputs.

### DETAILED DESCRIPTION OF THE INVENTION

The following description is based on a preferred embodiment of the invention, applied to an audio amplifier. However, as will be evident to anyone skilled in the art, the invention is not limited to a particular embodiment, but can also be applied to, for example, multimedia amplifiers, sound mixers, audio processors, etc.

In the case of the amplifier, the main feature that gives it its multimedia name is its ability to receive audio from several different audio sources, amplify them and feed speakers and/or other amplifiers.

Multimedia integrated circuits, MMIC, are components used in MP3 Player cards as audio sources. They are called multimedia because they receive and play audio from various sources, such as FM, Bluetooth broadcasting, P2 and/or P3 connection, SDCard, microphone. They also have volume control, equalizer, High and Low Pass filters, Fader and more.

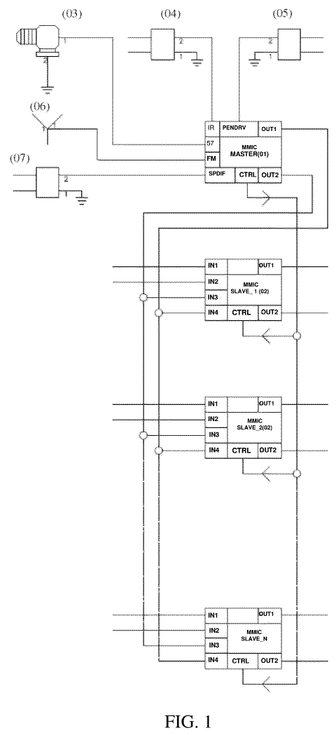

FIG. 1 illustrates the basic topology which can be adapted in different ways according to the various specific types of application (for example, different analog inputs which will be processed and result in different outputs). The generic analog audio inputs are combined with the inputs processed by the master MMIC, Bluetooth with or without broadcast (3), USB (5), SPDIF (7) and FM analog input (6) via the slave MMICs and result in generic processed audio outputs. In this case, each slave MMIC receives two analog inputs and two inputs from the master MMIC. The master MMIC also has an infrared control (4) that allows remote control of its operations.

Generic inputs and outputs mean that they can be adapted to meet the user's needs, for example by using analog RCA and Speaker Input Wire inputs or outputs for a 4-channel amplifier, or “N” channels and auxiliary Pre Out processed digitally or not.

In this embodiment, the master MMIC is responsible for controlling all the slave MMICs, as well as receiving the audio sources normally available on MP3 cards and other features such as remote control and optical audio input. Finally, the master MMIC also has the function of interfacing with the user via display, buttons or applications on mobile devices (such as smartphones, tablets) through Bluetooth communication.

It is important to mention, however, that preferably all MMIC units used have the same processing capacity. However, the slave MMIC units differ from the master MMIC by either lacking digital input interfaces or having them inoperative or operative. In this arrangement, the slave MMIC units serve the function of providing additional processed output channels to the circuit, where for every two new outputs, a new slave MMIC is added, enabling easy scalability of the circuit to meet the desired number of channels. Optionally, in an alternative embodiment, there is also the possibility of having a master MMIC with a lower capacity than the slave MMIC.

In addition, the slave MMICs are responsible for processing the audio as determined by the master MMIC via the user interface. In short, the slave MMICs (Slave 1, Slave 2) have the audio processing function with parameters set by the master MMIC. These parameters can be commands and information exchanged between the master MMIC and the user via the defined interface and between the master MMIC and the slave MMICs.

In this sense, the slave MMICs also receive analog and digital signals from the master MMIC, making digital audio traffic between the MMICs possible.

On this occasion, user commands can also parameterize the internal processors of these MMICs to perform numerical audio processing in order to, in practice, create, for example, filters (LPF, HPF), equalizers, a delay in the sound, bass boost, phase inversion, increase and decrease of gain in the signal, among others.

The audio to be processed can come from various external sources. Examples of external sources are RCA, Speaker Input Wire, Bluetooth with or without broadcasting, FM receiver, USB, SD Card, among others.

Through this arrangement, it is possible for the master MMIC together with the two slave MMICs to perform the same function as the DSP, microcontroller and analog/digital and digital/analog converters. In addition, as many slave MMICs as necessary can be added to cover the various types of inputs and outputs required.

As you can see, as well as replacing complex and expensive components such as DSPs, this arrangement also has the advantage of easy scaling of the number of channels desired.

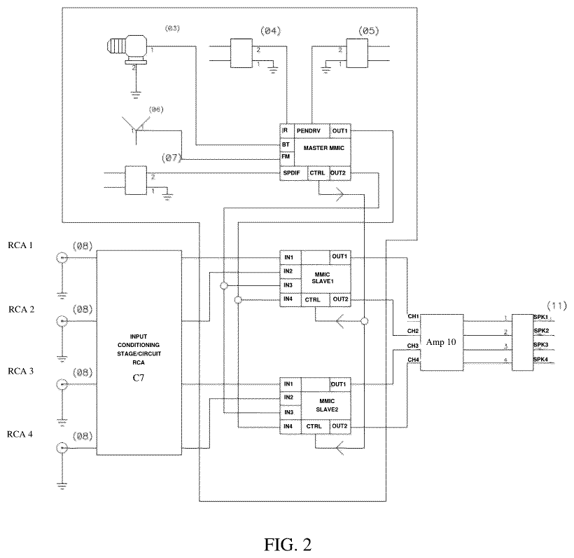

FIG. 2 illustrates an embodiment of the stepped control system with dedicated integrated of the present invention, in this case applied to a 4-channel amplifier that uses a master MMIC together with two slave MMICs (Slave 1 and Slave 2).

In this embodiment, the analog audio inputs are RCA and are routed directly to an RCA input conditioning circuit to be treated and ensure that they reach the other parts of the circuit in a uniform manner. In addition to the analog RCA inputs, we also have Bluetooth broadcasting (3) (two-way transmitter and receiver function), USB (5), FM antenna (6), SPDIF (7) which are played back by the master MMIC, and the master MMIC also has an infrared control (IR Control) (4).

Thus, after passing through the conditioning circuit, the RCA inputs are routed to the slave MMICs along with the digital and analog inputs (in the case of FM) reproduced by the master MMIC. In this arrangement, each slave MMIC is capable of receiving two RCA inputs and two outputs from the master MMIC, multiplexing the choice of each pair of inputs by the master control (CTRL) in which each slave MMIC results in two output channels.

The output channels of the slave MMICs are then connected to an amplifier circuit (Amp 10) which amplifies the inputs and provides outputs for the speakers (11).

In summary, the stepped system with dedicated integrated circuits comprises a master MMIC, which receives the analog (FM) and digital (USB, SPDIF, Bluetooth with or without broadcasting) signals, forwarding these digitally processed audio signals (OUT1 and OUT2 signals from the master) and control signals (CTRL) to several other slave MMICs according to the necessary scaling, where the multiplexing of generic inputs or inputs from the master MMIC (OUT1 and OUT2) is given as an option, thus providing the user with the option to scale the generic analog inputs with the digitally processed inputs from the master MMIC.

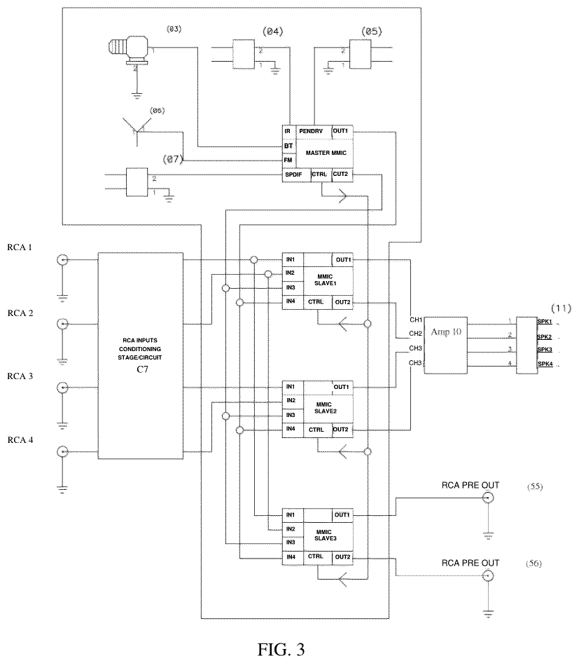

FIG. 3 is a similar circuit to FIG. 2, however, a third slave MMIC is applied, using the system's scaling feature, in order to generate two additional audio channels that are routed to auxiliary RCA Pre Out outputs (55, 56) with or without signal processing.

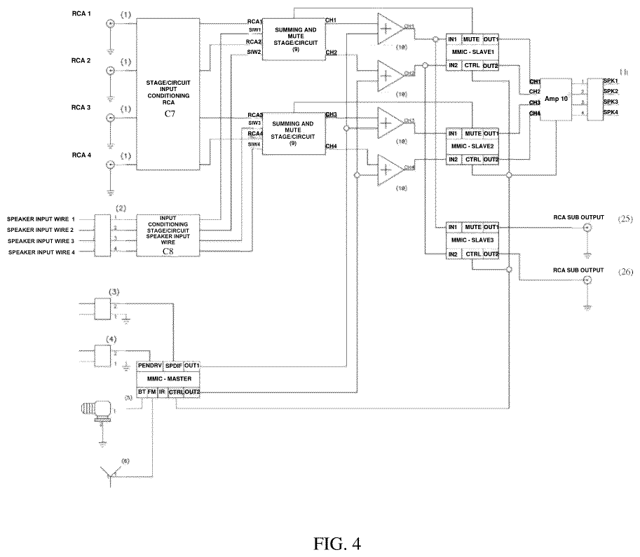

As illustrated in FIG. 4, an embodiment of the stepped control system with dedicated integrated circuit of the present invention, in this case applied to a 4-channel amplifier that uses, in a similar way to FIGS. 2 and 3, a master MMIC together with two slave MMICs (Slave 1, Slave 2), eliminating the need for more sophisticated audio equipment such as DSPs and microcontrollers that significantly increase the final product cost, often also overengineering the circuit for the final application.

In this exemplary embodiment of the present invention (FIG. 4), the control system applied to the multimedia amplifier circuit comprises two types of analog inputs, RCA and Speaker Input Wire. RCA and Speaker Input Wire inputs are physically and electrically different.

In the embodiment illustrated in FIG. 4, in view of these differences, the RCA analog inputs (RCA1, RCA2, RCA3, RCA4) are routed to an RCA input conditioning circuit (C7) and the Speaker Input Wire analog inputs (SIW1, SIW2, SIW3, SIW4) are routed to a Speaker Input Wire input conditioning circuit (C8). Thus, even given the difference in the signal of each of these outputs, the conditioning circuit treats their respective inputs to ensure that these signals arrive at the other stages with the same electrical characteristics.

In other words, the input conditioning circuits (C7, C8) have the function of processing the signals coming from the RCA and Speaker Input Wire inputs in order to equalize them before the other stages. Generally speaking, these signal conditioning circuits are circuits that treat the RCA and Speaker Input Wire signals differently so that they arrive the same at the next stages, which are shared with everyone, hence the summing stage, where all the inputs are joined together so that from then on they travel along the same path.

As illustrated in FIG. 4, the control system applied to the multimedia amplifier circuit also includes at least two summing and mute circuits (9) configured to sum, mix or reset the audio level. The purpose of this circuit is primarily to sum the RCA and Speaker Input Wire inputs, joining an RCA input and a Speaker Input Wire input to form a channel.

In this embodiment (FIG. 4), the first summing and mute circuit (9) receives a pair of RCA inputs (RCA1, RCA2) and a pair of Speaker Input Wire inputs (SIW1, SIW2) interleaved, resulting in two channels (CH1, CH2) and the second summing and mute circuit (9) receives the other from the pair of RCA inputs (RCA3, RCA4) and Speaker Input Wire inputs (SIW3, SIW4) in an interleaved manner resulting in another two channels (CH3, CH4).

In addition, FIG. 4, similarly to the previous figures, the master MMIC is used in this system to play audio from digital and analog inputs (in the case of the FM input).

In the embodiment illustrated in FIG. 4, after passing through the master MMIC, the audio is routed to four summing circuits (10) whose purpose is to sum the channels resulting from the summing and mute circuits (9) with the audio coming from the master MMIC.

In the embodiment illustrated in FIG. 4, the summing circuits (10) each receive a channel from the summing and mute circuits (CH1, CH2, CH3, CH4) and an output from the master MMIC (OUT1, OUT2). As a result, the four summing circuits join the analog audio summed through the summing and mute circuit with the analog and digital inputs reproduced by the master MMIC, thus producing four resulting channels (one for each summing circuit (10)), which will be routed to the slave MMICs.

In this embodiment (FIG. 4), two channels are used for each slave MMIC, so the two summing circuits (10) direct their output channels to a first slave MMIC (Slave 1) and the other two summing circuits (10) direct their output channels to a second slave MMIC (Slave 2).

Furthermore, in the embodiment illustrated in FIG. 4, the slave MMICs are additionally connected to the mute and summing circuits (9) so that, on command from the master MMIC and through user action, they can activate the audio mute function.

Finally, in the embodiment illustrated in FIG. 4, after the audio has been processed and the RCA and Speaker Input Wire analog inputs have been joined with the inputs reproduced by the master MMIC (already configured), each slave MMIC produces two outputs. each slave MMIC produces two outputs which are directed to an amplification circuit (Amp 10) which amplifies the inputs and provides outputs for the speakers (11).

In addition, similar to FIG. 3, a third slave MMIC (Slave 3) is employed and, instead of being directed to the amplifier stage like the other two slave MMICs (Slave 1, Slave 2), it is made available via RCA outputs, making it possible to connect it to an external amplifier of the desired power.

In the embodiment illustrated in FIG. 4, the control system applied to the multimedia amplifier circuit can also be adjusted to meet the user's needs in terms of the number of channels desired, with no limit on the number of channels/outputs. In this embodiment, an example of an application would be to connect the four amplified outputs to a vehicle's internal loudspeakers, directing 100 W to each loudspeaker and connecting an external amplifier to the RCA output of the third slave MMIC (Slave 3).

If the user wishes to adapt the system in this embodiment (FIG. 4) to be applicable to an amplifier with more channels, it is sufficient that for every two extra channels, a new slave MMIC is added in subordination to the master MMIC. In this way, each pair of extra channels passes through the IN1 and IN2 inputs of its respective slave MMIC and exits through the OUT1 and OUT2 outputs.

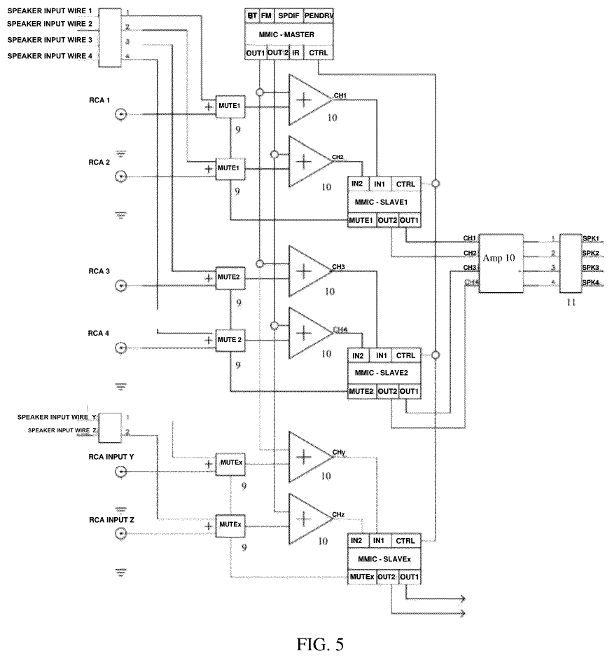

FIG. 5 illustrates an alternative embodiment of the present invention. Similarly to FIG. 4, the RCA and Speaker Input Wire inputs are routed to a summing and mute circuit (9) that unites the RCA and Speaker Input Wire inputs into a single channel. This channel resulting from the summing and mute circuit (9) is then connected to a summing circuit (10).

In the embodiment illustrated by FIG. 5, again, the master MMIC is used to play audio coming from digital inputs (or analog in the case of FM) and routes the audio to four summing circuits (10) that join the analog RCA and Speaker Input Wire inputs with the inputs played by the master MMIC, producing four resulting channels comprising both types of inputs, analog and digital.

In the embodiment illustrated in FIG. 5, the summing circuits (10) forward their channels to two slave MMICs which each receive a pair of channels. Similarly to FIG. 4, the slave MMICs are also connected to the mute and summing circuits (9) so that, under command from the master MMIC and through user action, they can activate the audio mute function

In particular, FIG. 5 illustrates the possibility of scaling the system. An N number of RCA and Speaker Input Wire inputs can be connected to N summing and mute circuits (9) where for every two additional channels desired, a new slave MMIC (Slave X) just needs to be added, thus generating another two outputs to be connected according to the user's needs.

Alternatively, if the system is to be used in an amplifier with a maximum of two channels, it is possible to remove the slave MMICs and use the master MMIC as the digital audio source.

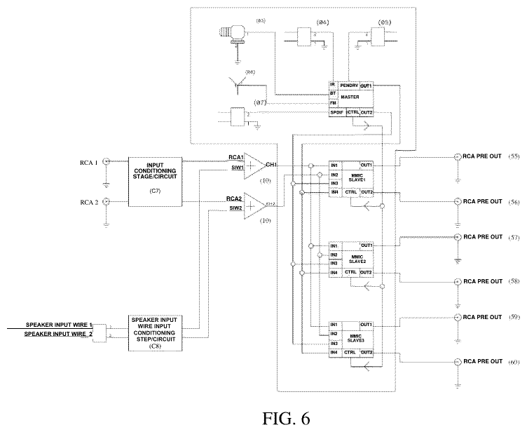

FIG. 6 illustrates another alternative embodiment of the stepped control system with dedicated integrated circuit of the present invention. In this embodiment, only one pair of RCA inputs and one pair of Speaker Input Wire inputs are used, which are routed to their specific input conditioning circuits.

In the embodiment shown in FIG. 6, after the RCA and Speaker Input Wire inputs pass through the input conditioning circuit, they are routed to a summing circuit in a similar way to the previous embodiments, i.e. each summing circuit receives only one RCA input and one Speaker Input Wire input. In this particular case, since we're talking about a pair of RCA inputs and a pair of Speaker Input Wire inputs, only two summing circuits are needed.

In the embodiment illustrated in FIG. 6, a master MMIC is used to play audio from digital inputs, such as an SPDIF input (7), a USB input (5), a Bluetooth antenna input with or without broadcasting (3) and analog inputs such as an FM antenna input (6). Finally, it is also connected to an infrared control input (IR control) (04).

In the embodiment illustrated in FIG. 6, each slave MMIC has 4 inputs, where the IN3 and IN4 inputs receive digital source signals from the master MMIC and also receive the already summed signals (IN1 and IN2) from the sum of the RCA and Speaker Input Wire inputs (summing R channels and summing L channels), two channels per input type. The CTRL (control) signal from the master MMIC multiplexes the channels to be routed to the Rca Pre Out outputs (55, 56, 57, 58, 59, 60).

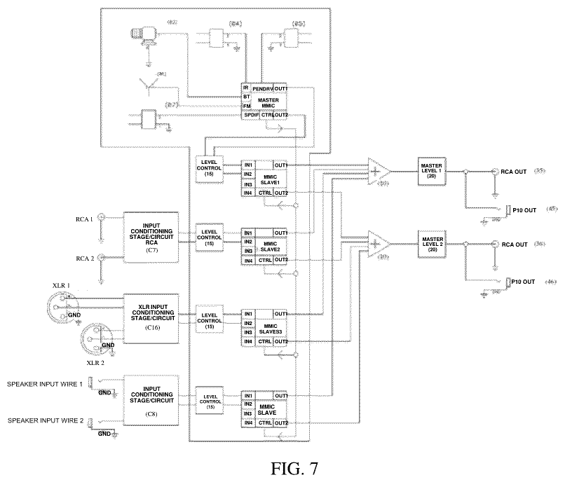

FIG. 7 illustrates yet another alternative form of the system where, in addition to the RCA (RCA1, RCA2) and Speaker Input Wire (SIW1, SIW2) inputs, it also has two XLR inputs (XLR1, XLR2). In this signal mixing system, the signals digitally processed by the master MMIC (SPDIF, USB, and Bluetooth with or without broadcasting) are mixed in the summing circuit with the inputs coming from the analog system via the XLR, P10, RCA connectors.

In the embodiment illustrated in FIG. 7, XLR inputs and their associated connectors are commonly applied to microphone and sound mixer connections. They can have from 3 to 7 metal pins and can have a lock to prevent accidental disconnection. In addition, it is a balanced input, avoiding noise and interference.

Alternatively, another standard of inputs specific to the audio segment used in this embodiment is P10, combined or not with XLR inputs, commonly used to connect musical instruments and/or equipment, such as digital audio processors, guitars, external sound mixers, keyboards and others.

In the embodiment illustrated in FIG. 7, similarly to the RCA and Speaker Input Wire inputs, these P10 and XLR inputs are also routed to an input conditioning circuit to be treated and ensure that they reach the other parts of the circuit in a uniform manner.

In the embodiment shown in FIG. 7, a gain controller (Level Control 15) and a Master Level are also used. In the context of the present invention, gain controllers are individual gain controls (Level Control 15), where each track of a product can be adjusted independently to best suit the sensitivity of each instrument or piece of equipment connected to independent tracks. The Master Level, in turn, after the independent adjustment made to each track by (Level Control 15), has the function of keeping all the tracks proportionally adjusted, maintaining the proportion defined by the gain controller (Level Control 15), but increasing or decreasing the gain of all the tracks at the same time, according to a user input. Finally, after passing through the Master Level (20), the signals are routed to the RCA Out (35, 36) and P10 Out (45, 46) outputs.

The use of specific inputs such as RCA and Speaker Input Wire should not be interpreted in a limiting way; these specific nomenclatures are only used for the purposes of clarity and directing the functionality of the invention. As any technician will appreciate, the analog inputs can be diverse, including but not limited to RCA, XLR, P10, P3, P2 and Speaker Input Wire.

Although only a few examples of the system of the present invention have been presented here, which replaces the use of a DSP, microcontroller and converters with an arrangement of master MMIC with slave MMIC in question, it should be understood that changes can be made to the shape and arrangement of the different component parts of the device, without departing from the proposed inventive concept.

1. A stepped control system with dedicated integrated circuit, said control system comprising:
an analog audio input receiver circuit configured to receive analog audio inputs;
an audio processor circuit for processing audio sources, the audio processor circuit comprising:
a master MMIC acting as a digital and analog audio player and configured to receive digital audio inputs and at least one audio processing command from a user;
wherein the master MMIC receives the analog audio inputs from the analog audio input receiver circuit, so that audio signals from the analog and digital audio inputs are routed to audio outputs of the master MMIC after the audio signals have been processed by the master MMIC.

2. The stepped control system with dedicated integrated circuit, according to claim 1, further comprising at least two slave MMICs (Slave 1, Slave 2) acting as audio processors to process the audio sources when there are more than three audio channels;
in which the analog audio inputs are connected to processing inputs of said at least two slave MMICs (Slave 1, Slave 2) together with an audio output from the master MMIC;
in which each slave MMIC (Slave 1, Slave 2) of said at least two slave MMICs (Slave 1, Slave 2) receives two analog audio inputs, and two audio outputs from the master MMIC;
where the at least two slave MMICs (Slave 1, Slave 2) generate generic processed audio outputs; and
in which processing parameters of said at least two slave MMICs (Slave 1, Slave 2) are determined by the Master MMIC.

3. The stepped control system with dedicated integrated circuit, according to claim 1, further comprising a summing and mute circuit (9) configured to at least one of sum or mix the analog audio inputs, wherein the summing and mute circuit (9) is additionally configured to mute the analog audio inputs.

4. The stepped control system with dedicated integrated circuit, according to claim 2, further comprising an amplifier integrated circuit (Amp 10) configured to receive the generic processed audio outputs of the at least two slave MMICs (Slave 1, Slave 2).

5. The stepped control system with dedicated integrated circuit, according to claim 1, further comprising a speaker output (11) configured to receive outputs of the amplifier circuit (Amp 10).

6. The stepped control system with dedicated integrated circuit, according to claim 1, further comprising at least one first pair of RCA analog inputs (RCA1, RCA2), at least one second pair of RCA analog inputs (RCA3, RCA4), at least one first pair of Speaker Input Wire analog inputs (SIW1, SIW2), and at least one second pair of Speaker Input Wire analog inputs (SIW3, SIW4).

7. The stepped control system with dedicated integrated circuit, according to claim 6, further comprising a first summing and mute circuit (9) and a second summing and mute circuit (9), wherein the first summing and mute circuit (9) is configured to receive the at least one first pair of analog RCA inputs and the at least one first pair of Speaker Input Wire analog inputs (RCA1, SIW1, RCA2, SIW2) from conditioning circuits (C7, C8); and
the second summing and mute circuit (9) is configured to receive the at least one second pair of RCA analog inputs and the at least one second pair of Speaker Input Wire analog inputs (RCA3, SIW3, RCA4, SIW4) from the conditioning circuits (C7, C8).

8. The stepped control system with dedicated integrated circuit, according to claim 2, further comprising at least a first pair of summing circuits (CH1, CH2) and at least a second pair of summing circuits (CH3, CH4); wherein each summing circuit of the at least first and second pairs of summing circuit (CH1, CH2, CH3, CH4) is configured to receive an output from a summing and mute circuit (9) and an output from the master MMIC; and
where outputs of the at least first pair of summing circuits (CH1, CH2) connect to an input of the first slave MMIC (Slave 1), and outputs of the at least second pair of summing circuits (CH3, CH4) connect to an input of the second slave MMIC (Slave 2).

9. The stepped control system with dedicated integrated circuit, according to claim 1, wherein the analog audio inputs can be any one of RCA, XLR, P10, P3 or Speaker Input Wire.

10. The stepped control system with dedicated integrated circuit, according to claim 2, characterized in that the at least two slave MMICs (Slave 1, Slave 2) are configured to drive a summing and mute circuit (9) of the analog audio inputs.

11. The stepped control system with dedicated integrated circuit, according to claim 10, wherein the at least two slave MMICs (Slave 1, Slave 2) also receive an analogue and digital signal from the master MMIC, enabling audio traffic between the at least two slave MMICs.

12. The stepped control system with dedicated integrated circuit, according to claim 1, wherein the master MMIC is configured to receive information from Bluetooth communication with or without broadcast.

13. The stepped control system with dedicated integrated circuit, according to claim 1, wherein said stepped control system is applied in at least one of multimedia, processors, sound mixers or audio amplifiers.
